(19) United States
(12) Patent Application Publication
(10) Pub. No.: US 2025/0393286 A1
(43) Pub. Date: Dec. 25, 2025

(54) FABRICATION METHOD FOR FORMING A TERRACED GATE OXIDE AND GATE OXIDE STRUCTURE FORMED BY USING THE SAME

(71) Applicant: National Yang Ming Chiao Tung University, Hsinchu City (TW)

(72) Inventor: Bing-Yue Tsui, Hsinchu City (TW)

(73) Assignee: National Yang Ming Chiao Tung University, Hsinchu City (TW)

(21) Appl. No.: 18/829,451

(22) Filed: Sep. 10, 2024

(30) Foreign Application Priority Data
Jun. 25, 2024 (TW) 113123605

(51) Int. Cl. H01L 29/423; H01L 21/04; H01L 21/28; H01L 29/06; H01L 29/08; H01L 29/16; H01L 29/66; H01L 29/739; H01L 29/78

(52) U.S. Cl. CPC H10D 64/516; H01L 21/0465; H01L 21/28185; H10D 12/032; H10D 12/441; H10D 30/0291; H10D 30/66; H10D 62/157; H10D 62/8325; H10D 62/10

(57) ABSTRACT

A fabrication method for forming a terraced gate oxide and the formed terraced gate oxide structure are provided. Sidewall barrier layers are provided in a high power device after high-temperature JFET ion implementation process. A second ion implementation process is subsequently applied under room temperatures to form an amorphous layer at the JFET top surface. After removing hard masks and sidewall barrier layers, rest processes are carried out. As for growing the gate oxide, since oxidation rate of the amorphous layer is greatly higher than that of the channel region and of the JFET region, a terraced gate oxide structure can be fabricated. Meanwhile, a bottom of the terraced gate oxide structure is underneath the device surface. The present invention is thus advantageous of reducing both the parasitic gate to drain capacitance and corner curvature of the gate electrode, thereby reduce electric field enhancement effects and avoid reliability degradation.

### BACKGROUND OF THE INVENTION

This application claims priority for the TW application No. 113123605 filed on 25 Jun. 2024, the content of which is incorporated by reference in its entirely.

### FIELD OF THE INVENTION

The present invention relates to process fabrication techniques for reducing a parasitic gate to drain capacitance of high power devices. More particularly, the present invention is related to a fabrication method for forming a terraced gate oxide structure and the gate oxide structure formed by using the same, in which the bottom of the formed terraced gate oxide structure can be controlled underneath and lower than a top surface of the device's channel region. As such, the electric field crowding and enhancement effect generated at the corners of the gate electrode of the device can be suppressed at the same time.

### DESCRIPTION OF THE PRIOR ART

In general, it has been acknowledged that, high power devices have been widely used in various power electronics fields, including: switching elements, motor control, consumer electronics, uninterruptible power systems and so on, due to their unique features of low power consumption, high voltage endurance, rapid switching speed, large safe operating range and so on. Since the applications of power integrated circuits and devices in the electrical and related electronic fields are gradually increasing, and the design, manufacture and working conditions of the high power devices are distinct from those of general low power devices, when considering design processes of high power devices, it is usually necessary to give priority to the voltage and current range that the device can withstand, as well as power, usage durability, and reliability, etc. of the device.

Please refer to FIG. 1, which shows a schematic structural diagram of a traditional Vertical Double Diffused Metal Oxide Semiconductor Field Effect Transistor (VDMOSFET) in the prior art. In such a conventional VDMOSFET, the VDMOSFET structure comprises an N-type semiconductor substrate (N+ sub) 102, an N-type drift region (N-drift) 104, N-type heavily doped regions (N+) 121, 122, P-type heavily doped regions (P+) 131, 132, P-type well regions (P-well, or P-base) 161, 162, a drain terminal 100, a gate terminal (Poly-Si) 201, and a gate oxide layer 203. In general, whether a silicon (Si) or silicon carbide (SiC) material is used, it has been verified as one of the most matured options for implementing high power MOSFETs. Its advantages include that process methods are nearly the same as those of conventional low voltage MOSFETs. In addition, the device reliability and breakdown mechanism are also similar to those in the conventional low voltage MOSFETs due to its planar channel. However, the VDMOSFET structure still encounters unavoidable disadvantages, for instance: a junction field effect transistor (JFET) region 106 is usually formed and observed between the two adjacent P-well regions 161 and 162, and as a result, the common junction field effect transistor effect (JFET effect) will be induced significantly.

In specific, the P-well region configured between the JFET region 106 and the N+ regions 121, 122 is the channel region of the transistor structure. And mostly in one cell, there will be a left and a right channel, each electrically connected with the gate terminal 201. As such, it causes the gate terminal 201 overlapping with the JFET region 106, forming a parasitic gate to drain capacitance (C_{GD}). Since it is known that the parasitic gate to drain capacitance (C_{GD}), also known as the feedback capacitance or the reverse transfer capacitance (Cᵣₛₛ), is included in the input capacitance (Cᵢₛₛ) and the output capacitance (Cₒₛₛ), such parasitic gate to drain capacitance is a key factor to affect the transistor switching speed and switching power consumption. When the parasitic gate to drain capacitance (C_{GD}) increases, it accordingly leads to an increased input capacitance (Cᵢₛₛ) and output capacitance (Cₒₛₛ), thereby having a severe negative impact on the dynamic characteristics, switching speed, power loss, etc. of the power transistor device. As for in the current technologies, it has been known that several techniques have been provided in the prior arts in order to modify the existing gate oxide structure. And by providing a modified gate oxide structure, a reduced parasitic gate to drain capacitance (C_{GD}) is expected. Nevertheless, regarding the currently existing techniques, challenges remain and a much lower parasitic gate to drain capacitance (C_{GD}) is still to be expected for the power MOSFET devices nowadays.

As a result, it is believed that in the current technologies, one of the main design criteria for a VDMOSFET structure comprises how to reduce the parasitic gate to drain capacitance (C_{GD}) of the power transistor more efficiently without affecting its technical characteristics. And based on such objectives, to overcome the above-mentioned problems, it is obviously expected that there is indeed an urgent need for the professionals in the field for proposing a new process method to be developed that can effectively solve the above-mentioned problems occurring in the prior design. And by employing such modified process method, a much lower parasitic gate to drain capacitance (C_{GD}) of the power transistor can be achieved. Meanwhile, an easier and more accurate process control can also be obtained. As a result, by providing the present invention, it is believed that those long-standing shortcomings in the prior arts can be successfully solved. Hereinafter, the detailed specific implementations will be fully described in the following paragraphs.

### SUMMARY OF THE INVENTION

In order to overcome the above-mentioned disadvantages, one major objective in accordance with the present invention is to provide a fabrication method for forming a terraced gate oxide. By employing the disclosed fabrication method, a terraced gate oxide structure can be successfully formed in a high power device, and thus the gate oxide layer is formed in a terraced structure, having effectively increased thickness. Due to the terraced gate oxide structure, a lower parasitic gate to drain capacitance (C_{GD}) is achieved.

In addition, another objective of the present invention is to fabricate a modified and improved gate oxide layer, which is characterized by having a terraced structure and showing a semi-sunken thick oxide layer structure. Since the gate oxide thickness above the JFET region is thicker than the oxide thickness in the channel region, and half of the gate oxide thickness is down below the top surface of the channel region, in addition to reducing the parasitic gate to drain capacitance (C_{GD}), the corner electric field crowding effect generating at the gate oxide layer thickness transition (from thin to thick) can be suppressed at the same time. As a result, it is believed that the breakdown voltages and reliability performances of the power device can be well maintained by employing the present invention.

Moreover, when N-type doped ions are taken into considerations for performing room temperature ion implantation, then a surface concentration of the JFET region underneath the thick oxide layer can be further increased so as to avoid an increased specific on resistance (R_{on,sp}). Even more, a reduced specific on resistance (R_{on,sp}) can be possibly obtained.

On account of the above, the present invention is proposed to provide a fabrication method for forming a terraced gate oxide structure and the gate oxide structure formed by using the same. According to the present invention, a high temperature JFET ion implantation process is applied first, and afterwards, sidewall barrier layers are provided. After the sidewall barrier layers are disposed, a second ion implantation process is then applied at room temperatures, such that an amorphous layer is formed on a top surface of the JFET region. In view of the technical contents of the present invention, since the thermal oxidation rate of the amorphous layer is significantly greater than the thermal oxidation rate of its channel region and JFET region, a terraced gate oxide structure having thick gate oxide thickness is formed. And, the bottom of the formed gate oxide structure is down below its device surface. As a result, it is believed that, not only the parasitic gate to drain capacitance (C_{GD}) can be effectively reduced, but also the corner curvature of the gate electrode can be reduced at the same time. As such, the conventional electric field enhancement and crowding effect is suppressed, and the device's reliability degradation is avoided.

For achieving the above mentioned objectives, the technical solutions of the present invention are aimed to provide an improved and modified fabrication process method, which is applicable to form a terraced gate oxide structure, so as to reduce a parasitic gate to drain capacitance (C_{GD}) and ensure that such fabrication process method is advantageous of having better process control abilities.

According to the disclosed fabrication process method of the present invention, the disclosed fabrication method comprises a plurality of following steps:
(a): At first, a semiconductor substrate is provided, and an epitaxial layer is disposed on the semiconductor substrate. A first well region and a second well region are configured on the epitaxial layer, a first heavily doped region and a second heavily doped region are formed in the first well region, and a third heavily doped region and a fourth heavily doped region are formed in the second well region. A junction field effect transistor (JFET) region is formed between the first well region and the second well region.

According to the embodiment of the present invention, the disclosed semiconductor substrate, the epitaxial layer, the first heavily doped region and the third heavily doped region have a first semiconductor conductivity type. On the contrary, the first well region, the second well region, the second heavily doped region and the fourth heavily doped region have a second semiconductor conductivity type. The first semiconductor conductivity type and the second semiconductor conductivity type are opposite conductivity types. For instance, when the first semiconductor conductivity type is an N-type semiconductor conductivity type, the second semiconductor conductivity type is a P-type semiconductor conductivity type. On the contrary, when the first semiconductor conductivity type is a P-type semiconductor conductivity type, then the second semiconductor conductivity type will be an N-type semiconductor conductivity type. The present invention is not limited by the certain semiconductor conductivity types used in the circuit configurations.

Moreover, according to the embodiment of the present invention, the second heavily doped region is disposed adjacent to the first heavily doped region, and the second heavily doped region and the first heavily doped region are commonly disposed in the first well region. In practice, a source ion implantation process can be carried out so as to form the disclosed first heavily doped region in the first well region.

By adopting the similar technical manners, the fourth heavily doped region is configured adjacent to the third heavily doped region, and the fourth heavily doped region and the third heavily doped region are commonly disposed in the second well region. In practice, a source ion implantation process may be also carried out so as to form the disclosed third heavily doped region in the second well region.
(b): After that, a first hard mask layer is provided and disposed on the first heavily doped region, the second heavily doped region and the first well region. A second hard mask layer is provided and disposed on the third heavily doped region, the fourth heavily doped region and the second well region. According to the embodiment of the present invention, between the first hard mask layer and the second hard mask layer is a first spacing.

In one preferred embodiment of the present invention, the first hard mask layer and the second hard mask layer can be made of silicon dioxide (SiO₂).
(c): And subsequently, through the first spacing, a first ion implantation process is performed.

In specific design manners, according to the embodiment of the present invention, a process temperature of the first ion implantation process is greater than 500 Celsius degrees (° C.). An ion implantation energy of the first ion implantation process is between 100 keV and 1000 keV. And an ion implantation dosage of the first ion implantation process can be controlled between 10¹¹ cm⁻² and 10¹³ cm⁻².
(d): And then, the present invention proceeds to provide sidewall barrier layers. Each sidewall barrier layer is disposed on one sidewall of the hard mask layer. Specifically, one sidewall barrier layer is formed on one sidewall of the first hard mask layer and, one sidewall barrier layer is formed on another sidewall of the second hard mask layer. The two sidewall barrier layers are facing each other. Each sidewall barrier layer is disposed corresponding to a sidewall of the first hard mask layer and corresponding to a sidewall of the second hard mask layer. The sidewall of the first hard mask layer is opposite to the sidewall of the second hard mask layer. As a result, by such configurations, it is obtained that a second spacing can be formed between the first hard mask layer covered with the sidewall barrier layer and the second hard mask layer covered with the sidewall barrier layer. And, according to the embodiment of the present invention, the second spacing is less than the above-mentioned first spacing.

Moreover, regarding the detailed process steps for forming the disclosed sidewall barrier layers, a plurality of process steps provided as follows, may be adopted in order to form the sidewall barrier layers:
(d-1): a low-pressure chemical vapor deposition (LPCVD) process can be used first to deposit a barrier layer; and
(d-2): an anisotropic etching process can be subsequently employed to etch the barrier layer, so as to form the sidewall barrier layer disposed corresponding to the sidewall of the first hard mask layer and the sidewall barrier layer disposed corresponding to the sidewall of the second hard mask layer, such that the second spacing is formed there in between.

In one embodiment, a thickness of the disclosed one sidewall barrier layer can be controlled between 0.1 μm and 0.5 μm. Preferably, one sidewall barrier layer can be made in a range of 0.2˜0.3 μm.

And therefore, as in the following step of (e): the present invention is able to proceed to perform a second ion implantation process through the second spacing, such that by employing the second ion implantation process, an amorphous layer is formed on a top surface of the JFET region after the second ion implantation process is performed and achieves in amorphizing the JFET region.

According to the embodiment of the present invention, it is operable that, a process temperature of the second ion implantation process is at room temperatures. An ion implantation energy of the second ion implantation process is between 5 keV and 30 keV. And an ion implantation dosage of the second ion implantation process is between 10¹⁴ cm⁻² and 10¹⁶ cm⁻². Moreover, the disclosed second ion implantation process can be employed by adopting ions, including phosphorus (P), nitrogen (N), argon (Ar), aluminum (Al), silicon (Si), oxygen (O), other N-type or P-type dopants, or inert ions.

As a result, according to the embodiment of the present invention, the present invention is able to fabricate an amorphous layer at a top surface of the JFET region, having a thickness less than 100 nm. Meanwhile, the JFET region underneath the amorphous layer can be still maintained as a single crystal layer having a single crystal state or a polycrystalline layer having a polycrystalline state.

As for regarding the material of the formed sidewall barrier layer, it is feasible that, the sidewall barrier layer is alternatively made of silicon dioxide (SiO₂), silicon nitride (Si₃N₄), polysilicon (poly-Si), or other solid films made of semiconductor materials that are resistant to the second ion implantation process disclosed in such process step.

(f): And afterwards, the sidewall barrier layers, the first hard mask layer and the second hard mask layer used in the previous steps are removed. And a thermal oxidation process is successively adopted such that the amorphous layer is oxidized and a terraced gate oxide is formed in the high power device by oxidizing amorphous layer.

According to the embodiment of the present invention, a thickness of the amorphous layer is less than 100 nm. And the JFET region underneath the amorphous layer is a single crystal layer or a polycrystalline layer. The process conditions of the thermal oxidation process used in the step of (f) include: using oxygen (O₂), water molecule (H₂O), or a mixture of hydrogen (H₂) and oxygen (O₂) as performing the thermal oxidation process.

As a result, since a thermal oxidation rate of the amorphous layer is 2 to 9 times greater than the thermal oxidation rate of the single crystal layer or of the polycrystalline layer, the present invention achieves in forming the terraced gate oxide, which includes at least a terraced region and a channel region, such that a gate oxide thickness in the terraced region is more than twice the gate oxide thickness in the channel region. Meanwhile, the gate oxide thickness in the terraced region is configured as extending down to a bottom of the amorphous layer. And a bottom of the gate oxide layer in the terraced region is lower than the top surface of the JFET region. And hence, it is believed that, a semi-sunken gate oxide layer structure is fabricated by employing the technical solution of the present invention.

In general, various modifications and variations to the present invention can be made by people who are skilled in the art, without departing from the scope or spirits of the invention. And yet, the present invention covers these modifications and/or variations provided that, they fall within the scope of the invention and its equivalent. The present invention is certainly not limited to the disclosed parameters and conditions as illustrated above.

Based on the above, by employing the disclosed process method, the present invention effectively forms a terraced gate oxide structure. Since the thermal oxidation rate of the amorphous layer is significantly higher than the thermal oxidation rate of its channel region and JFET region when growing the gate oxide in a high power device, a much thicker gate oxide layer formed in a terraced structure can be obtained, thereby effectively reduce the parasitic gate to drain capacitance C_{GD} in the high power device.

Meanwhile, by employing the disclosed fabrication method for forming a terraced gate oxide and the terraced gate oxide structure formed by using the same, since a bottom of the formed gate oxide structure is lower than its device surface, which provides a semi-sunken gate oxide layer structure, in addition to a reduced C_{GD}, it is believed that the corner curvature of the gate electrode as well as the electric field crowding and enhancement effect can be suppressed and reduced at the same time, avoiding the device's breakdown voltage and reliability degradation.

According to several applicable embodiments of the present invention, the high power device which the present invention can be applied to, may include, and not limited to a Vertical Double Diffused Metal Oxide Semiconductor Field Effect Transistor (VDMOSFET) structure, or an Insulated Gate Bipolar Transistor (IGBT) structure. And the semiconductor substrate of the high power device can be made of semiconductor materials including silicon (Si), silicon carbide (SiC), and so on for instance.

As a result, based on the above mentioned process method disclosed in the present invention, a terraced gate oxide fabrication method and terraced gate oxide structure are provided. Due to a high thermal oxidation rate of the amorphous layer formed in a room temperature ion implantation process, when growing the gate oxide layer, it can be obtained that its gate oxide thickness grown can be twice more than the gate oxide thickness in the channel region. As a result, not only the parasitic gate to drain capacitance (C_{GD}) is reduced, but also the electric field enhancement and crowding effect generated at the gate oxide layer thickness transition (from thin to thick) can be suppressed due to the semi-sunken thick gate oxide layer structure. And therefore, VBD (breakdown voltages) and reliability of the power device can be well maintained. Apart from these, when taking N-type doped ions for performing the room temperature ion implantation process, then a surface concentration of the JFET region underneath the thick oxide layer can be additionally increased so as to avoid an increased specific on resistance (R_{on,sp}). In a further embodiment, then the specific on resistance (R_{on,sp}) may possibly be reduced.

From another point of view, on a basis of such fabrication process method, the present invention also provides a kind of gate oxide structure, which is formed by using the above disclosed fabrication method for forming the terraced gate oxide. The proposed gate oxide structure includes at least a terraced region and a channel region, which is adjacent to and connecting with the terraced region. A gate oxide thickness in the terraced region is configured as extending down to a bottom of the amorphous layer. And the gate oxide thickness in the terraced region is more than twice the gate oxide thickness in the channel region.

According to the terraced gate oxide structure, a single crystal layer of a single crystal state or a polycrystalline layer of a polycrystalline state can be retained in the JFET region under the amorphous layer, such that the thermal oxidation rate of the amorphous layer can be expected as 2 to 9 times greater than the thermal oxidation rate of the single crystal layer or of the polycrystalline layer.

Moreover, according to one preferable embodiment of the present invention, the material of the semiconductor substrate used in the present invention may be, for example, preferably a silicon carbide (SiC) substrate. However, the process method and the terraced gate oxide structure formed therein the present invention are not limited to the disclosed silicon carbide material. Based on the same design manners, it is believed that the technical solutions disclosed in the present invention can also be widely applied to other semiconductor materials. For example, the material of the semiconductor substrate can also be made of silicon (Si), silicon carbide (SiC), and so on. Besides, the types of transistors that the present invention can be applied to are not limited to transistors with N-type channels. It may also be applied to transistors with P-type channels. To sum above, it is obvious from such point of views, that according to the process method disclosed in the present invention and the terraced gate oxide layer formed in the present invention, the disclosed application is advantageous of showing extremely high industrial applicability and technical compatibilities.

On account of the above, it is believed that the present invention proposes a fabrication method for forming the terraced gate oxide and the formed terraced gate oxide structure, itself. According to any one feasible embodiment of the present invention, it achieves in reducing the overlap area of the gate and drain electrodes effectively, so as to decrease the parasitic gate to drain capacitance (C_{GD}).

Also, regarding to another aspect of the advantages, the present invention also achieves in increasing the oxide layer thickness at the gate bottom. Therefore, the corner curvature of the gate electrode can be reduced at the same time, whereby breakdown voltages and reliability of the power device when adopting the present invention can be significantly improved.

It is worth emphasizing that, the embodiments disclosed in the present invention are merely described as taking silicon carbide as an illustrative exemplary example. The purpose is to enable those skilled in the art to fully understand the technical spirits of the present invention, but not intend to limit the application of the present invention. In other words, the process method disclosed in the present invention can be applied not only to silicon carbide substrates, but also to various semiconductor materials. The process method provided by the present invention can also be further applied to various semiconductor materials, and not limited to silicon carbide substrates.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic structural diagram of a basic structure of a conventional N-type VDMOSFET in the prior art.

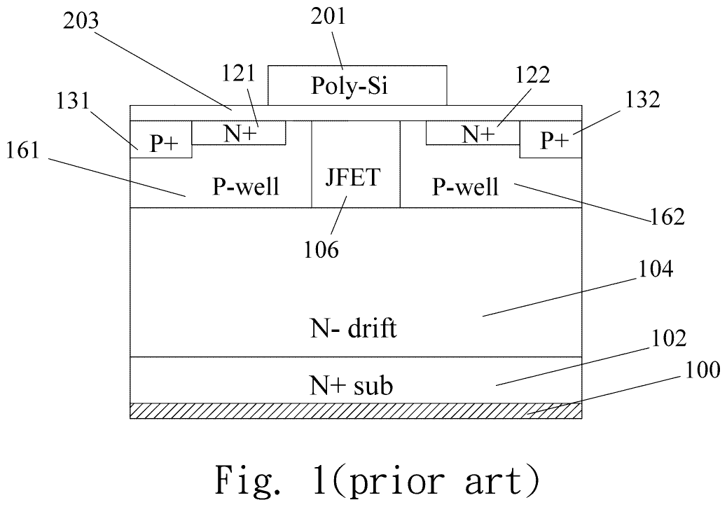

FIG. 2 shows a flow chart illustrating the steps of the fabrication method for forming a terraced gate oxide in accordance with one embodiment of the present invention.

FIG. 3 shows a schematic structural diagram of forming an N-type epitaxial layer on an N-type semiconductor substrate in accordance with one embodiment of the present invention.

FIG. 4 shows a schematic structural diagram from FIG. 3 after the well regions, source ion implantation process and heavily doped regions are defined.

FIG. 5 shows a schematic structural diagram from FIG. 4 after a first and a second hard mask layer are further deposited.

FIG. 6 shows a schematic structural diagram from FIG. 5 after a first ion implantation process is performed through the first spacing.

FIG. 7 shows a schematic structural diagram from FIG. 6 after each sidewall barrier layer is provided and disposed on one sidewall of the first and second hard mask layer.

FIG. 8 shows a schematic structural diagram from FIG. 7 after a second ion implantation process is performed through the second spacing.

FIG. 9 shows a schematic structural diagram from FIG. 8 after a thermal oxidation process is performed so as to grow and form the terraced gate oxide structure.

### DESCRIPTION OF THE PREFERRED EMBODIMENTS

It is to be understood that both the foregoing general description and the following detailed description are exemplary and are intended to provide further explanation of the invention as claimed.

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

In the following paragraphs, the present invention is aimed to disclose a fabrication method for forming a terraced gate oxide, as well as a terraced gate oxide structure by using such fabrication method. By employing the disclosed application of the present invention, a reduced parasitic gate to drain capacitance (C_{GD}) can be obtained in a high power device, improving the high-frequency characteristics of the device. In addition, it also helps to suppress the electric field crowding and enhancement effect generated at the thickened gate oxide layer and to eliminate the currently existing problems in the prior arts. The present invention is able to avoid the increasement of the R_{on,sp}. And even more, a reduced R_{on,sp} may possibly be achieved in a further aspect.

According to the disclosed technical contents of the present invention, a silicon carbide vertical double-diffused metal oxide semi-field effect transistor (VDMOSFET) of an N-type channel will be illustrated as an exemplary example for detailed descriptions. However, alternative similar transistor structures may possibly be applied as well according to the present invention. The present invention is certainly not limited to the embodiments disclosed below.

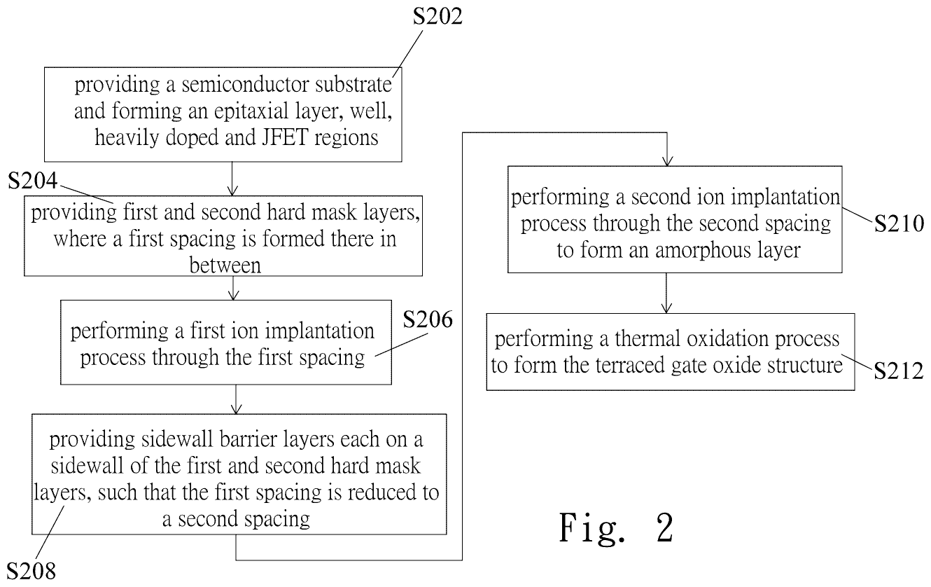

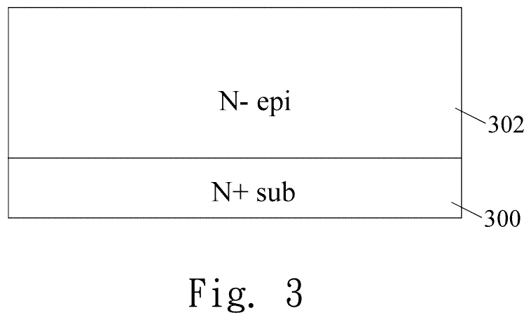

At first, please refer to FIG. 2, which shows a flow chart illustrating the proposed steps of a fabrication method for forming the terraced gate oxide in accordance with one embodiment of the present invention. The disclosed fabrication method includes the plurality of steps as: the steps of S202, S204, S206, S208, S210, and S212. By adopting the proposed fabrication method disclosed in the present invention, it is effective in forming a terraced gate oxide structure which is applicable to a high power device, meanwhile reducing its parasitic gate to drain capacitance (C_{GD}), corner curvature and electric crowding effect of the gate terminal. A better VBD and reliability of the high power device can be accomplished as well. For illustrating the disclosed fabrication method of the present invention, please refer to FIG. 3 to FIG. 9, which accompanying show schematic cross-sectional views of the structure of the VDMOSFET by employing the proposed method disclosed in the present invention. First, as referring to the step of S202 in FIG. 2, please find FIG. 3, in which a semiconductor substrate 300 is provided first. And an epitaxial layer 302 is disposed thereon the semiconductor substrate 300. In such step, according to one embodiment of the present invention, the semiconductor substrate 300 preferably, can be made of an N-type silicon carbide (SiC). In FIG. 3, it is illustrated as an N-type heavily doped substrate (N+ sub) 300. Afterwards, the epitaxial layer 302 is then formed on the semiconductor substrate 300. According to the embodiment of the present invention, an N-type silicon carbide epitaxial layer with a doping concentration of 1×10¹⁶ cm⁻³ and a thickness of 5.5 μm can be grown on the front side of the N+ heavily doped substrate (N+ sub) as the N-type epitaxial layer 302 (shown as N-epi) by epitaxial growth, so as to form the structure as shown in FIG. 3. However, it is worth noting that the semiconductor substrate material is not limited to N-type silicon carbide. In various other applicable embodiments of the present invention, alternative semiconductor materials can be generally used, or substrates directly made of silicon (Si) can be used. The following technical descriptions of the present invention are intended to simply use N-type SiC material as an exemplary example for describing the technical descriptions of the present invention. As a result, based on the same technical principles, those skilled in the art are able to alternatively take P-type semiconductor substrates for implementing the technical contents of the present invention. And such similar descriptions based on same principles, are therefore omitted in the following application hereinafter.

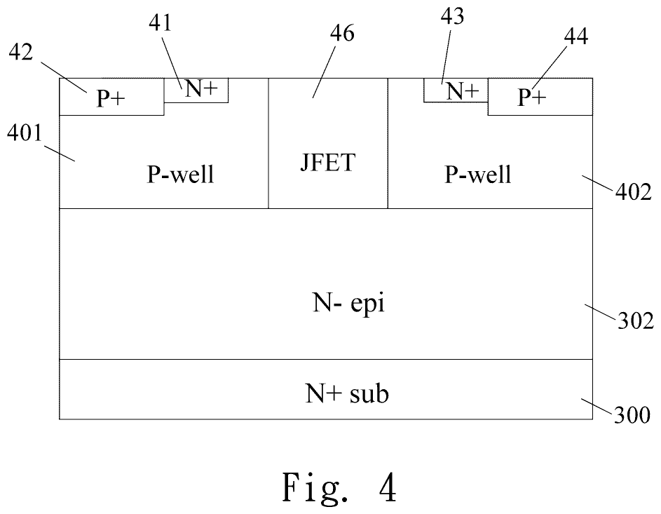

Please also refer to FIG. 4, in which a first well region 401 and a second well region 402 are configured on the epitaxial layer (N-epi) 302. According to the illustrative embodiment of the present invention, the semiconductor substrate 300 and the epitaxial layer 302 are illustrated as having a first semiconductor conductivity type while the first well region 401 and the second well region 402 are illustrated as having a second semiconductor conductivity type. The first and second semiconductor conductivity types are opposite conductivity types. As in the embodiment of the present invention when an N-type SiC is adopted, it is obvious that the disclosed first semiconductor conductivity type is an N-type semiconductor conductivity type and the disclosed second semiconductor conductivity type is a P-type semiconductor conductivity type. And therefore, based on such conductivity types, the first well region 401 and the second well region 402 of the second semiconductor conductivity type are indicated by “P-well” in the embodiment as shown in FIG. 4.

And subsequently, an RCA cleaning can be applied, and then, silicon dioxide can be deposited as a barrier layer. Later, a lithography process can be subsequently employed to define an N+ source window. Therefore, as shown in the embodiment of FIG. 4, then it can be obtained that a first heavily doped region 41 is formed in the above mentioned first well region 401. By employing the same process manners, it is believed that a third heavily doped region 43 can be formed in the above mentioned second well region 402. According to such embodiment of the present invention, the first heavily doped region 41 and the third heavily doped region 43 have the first semiconductor conductivity type as the semiconductor substrate 300 and the epitaxial layer 302 do. As a result, an N-type heavily doped region (N+) is used to refer to the first heavily doped region 41 and the third heavily doped region 43 in FIG. 4. In general, the first heavily doped region (N+) 41 and the third heavily doped region (N+) 43 can be formed respectively in the first well region (P-well) 401 and in the second well region (P-well) 402 by employing a source ion implantation process. That is, a source ion implantation process can be carried out to form the first heavily doped region (N+) 41 in the first well region (P-well) 401, and to form the third heavily doped region (N+) 43 in the second well region (P-well) 402.

And then, after the source ion implantation process is complete, the barrier layer is removed and the RCA cleaning is performed repeatedly. Subsequently, definition of the P-type heavily doped region (P+) and ion implantation process are employed for forming a second heavily doped region 42 and a fourth heavily doped region 44. According to the embodiment of the present invention, the second heavily doped region 42 and the fourth heavily doped region 44 have the second semiconductor conductivity type as the first well region 401 and the second well region 402 do. As a result, a P-type heavily doped region (P+) is used to refer to the second heavily doped region 42 and the fourth heavily doped region 44 in FIG. 4. In specific, the second heavily doped region (P+) 42 is disposed adjacent to the first heavily doped region (N+) 41, and the second heavily doped region (P+) 42 and the first heavily doped region (N+) 41 are commonly disposed in the first well region (P-well) 401. In addition, by employing the same process manners, then the fourth heavily doped region (P+) 44 is disposed adjacent to the third heavily doped region (N+) 43, and the fourth heavily doped region (P+) 44 and the third heavily doped region (N+) 43 are commonly disposed in the second well region (P-well) 402. As such, according to the embodiment of the present invention, a JFET (Junction Field Effect Transistor) region 46 is formed between the first well region (P-well) 401 and the second well region (P-well) 402.

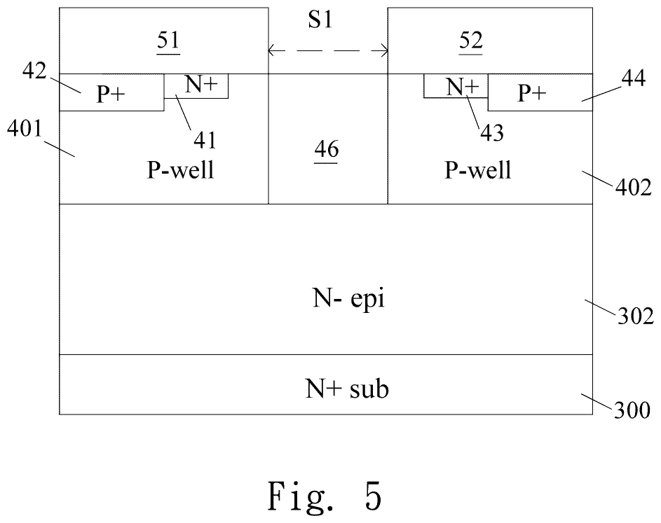

And next, as referring to the step of S204 in FIG. 2, after the well region, heavily doped region definitions and ion implantation are complete, a first hard mask layer and a second hard mask layer are subsequently deposited. According to the embodiment of the present invention as shown in FIG. 5, it can be seen that the first hard mask layer 51 is disposed on the first heavily doped region (N+) 41, the second heavily doped region (P+) 42 and the first well region (P-well) 401, and the second hard mask layer 52 is disposed on the third heavily doped region (N+) 43, the fourth heavily doped region (P+) 44 and the second well region (P-well) 402. The first hard mask layer 51 and the second hard mask layer 52 can be made of silicon dioxide (SiO₂), for instance, and it is apparent that a first spacing S1 is formed between the first hard mask layer 51 and the second hard mask layer 52.

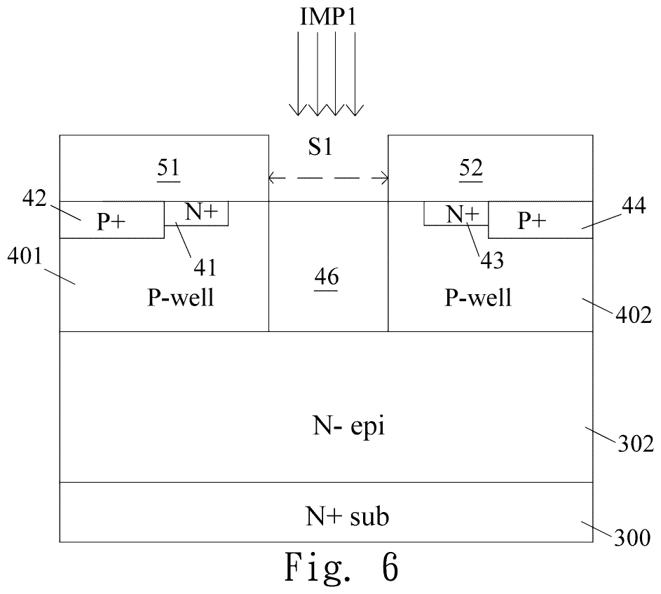

After that, the present invention proceeds to perform the step of S206 in FIG. 2, which is performing a first ion implantation process IMP1 through the first spacing S1 as shown in FIG. 6. Generally speaking, the first ion implantation process IMP1 is known as a conventional high temperature JFET ion implantation process, having a process temperature greater than 500 Celsius degrees (° C.), an ion implantation energy between 100 keV and 1000 keV and ion implantation dosage between 10¹¹ cm⁻² and 10¹³ cm⁻². Next on, after finishing the high temperature JFET ion implantation process in such process step (the disclosed first ion implantation process IMP1), the proposed fabrication method of the present invention regarding how to form the terraced gate oxide structure are to be fully described in details as referring to the following descriptions.

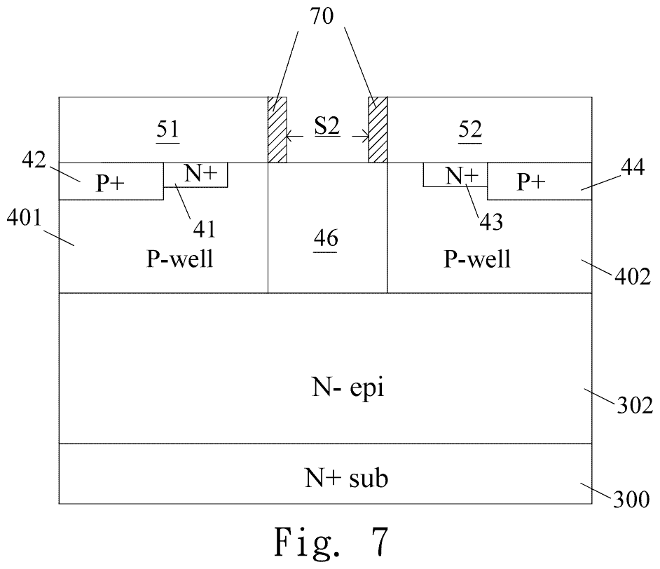

Please refer to FIG. 7 accompanying the step of S208 in FIG. 2. The present invention is operable to further dispose the sidewall barrier layers 70. As can be seen, each sidewall barrier layer 70 is provided and disposed on one sidewall of the first hard mask layer 51 and on one sidewall of the second hard mask layer 52. That is, one sidewall barrier layer 70 is disposed corresponding to a sidewall of the first hard mask layer 51 and the other sidewall barrier layer 70 is disposed corresponding to the sidewall of the second hard mask layer 52. The sidewall of the first hard mask layer 51 and the other sidewall of the second hard mask layer 52 are opposite and facing each other. As a result, by such configurations, it is apparent that after the sidewall barrier layers 70 are configured, between the first hard mask layer 51 covered with the sidewall barrier layer 70 and the second hard mask layer 52 covered with the sidewall barrier layer 70 is the second spacing S2. And such reduced second spacing S2 is apparently less than the foregoing first spacing S1. (see FIG. 5 and FIG. 6)

To be more specific, when performing such process step of S208 for forming the sidewall barrier layers 70 each on a sidewall of the first and second hard mask layer 51, 52, according to a preferred embodiment of the present invention, it is applicable to use a LPCVD (low-pressure chemical vapor deposition) process to deposit a barrier layer first, and after that, an anisotropic etching process can be carried out subsequently to etch the barrier layer, so as to form the sidewall barrier layers 70 as illustrated in FIG. 7. At the same time, the second spacing S2 is retained between the two sidewall barrier layers 70.

In general, the deposited material of the barrier layer can be, for example, silicon nitride (Si₃N₄). And yet the present invention is not limited thereto such materials. In other alternative embodiments of the present invention, the sidewall barrier layer 70 can be alternatively made of silicon dioxide (SiO₂), silicon nitride (Si₃N₄), polysilicon (poly-Si), or other solid films made of semiconductor materials that are resistant to a second ion implantation process, which will be applied later in the following fabrication process. Overall, the provided sidewall barrier layers 70 are disposed and configured in order to reduce and shorten the ion distribution range of the subsequent second ion implantation process such that the ion distribution range of the second ion implantation process does not overlap with the device's channel region. Due to such inventive objectives, a thickness of the sidewall barrier layer 70 is mostly controlled between 0.1 μm and 0.5 μm, preferably between 0.2 μm and 0.3 μm.

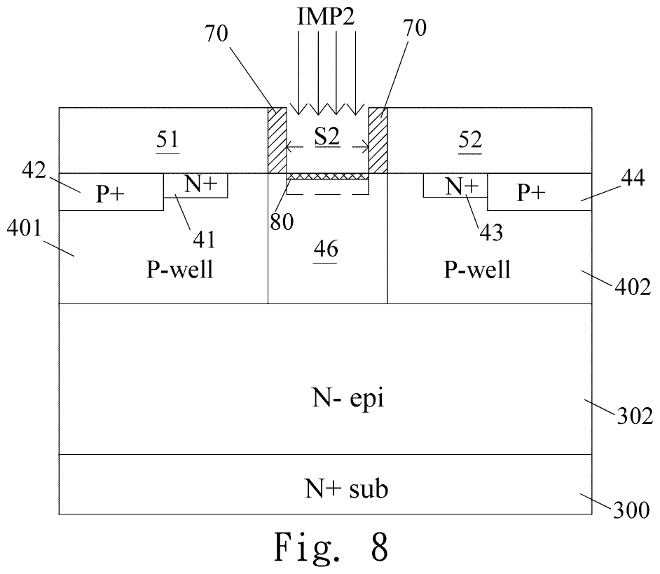

After that, please proceed to refer to the step of S210 in FIG. 2, since the second spacing S2 is obtained after the two sidewall barrier layers 70 are formed, the present invention is able to successively perform a second ion implantation process IMP2 through the second spacing S2, as shown in FIG. 8. According to the technical features of the disclosed process method, the second ion implantation process IMP2 is employed and adopted for amorphizing the JFET region 46, such that an amorphous layer 80 on a top surface of the JFET region 46 is formed.

According to the embodiment of the present invention, the provided second ion implantation process IMP2 in step S210 is distinct from the previous first ion implantation process IMP1. In specific, the disclosed second ion implantation process IMP2 is a kind of ion implantation process, performed in room temperatures (RT), having an ion implantation energy between 5 keV and 30 keV. Moreover, an ion implantation dosage of the second ion implantation process IMP2 is between 10¹⁴ cm⁻² and 10¹⁶ cm⁻², approximately. Generally, according to the feasible embodiments of the present invention, the possible ions used in the second ion implantation process IMP2 may include and not limited to: phosphorus (P), nitrogen (N), argon (Ar), aluminum (Al), silicon (Si), oxygen (O), other N-type or P-type dopants, or inert ions. In one practical configuration, the Applicants of the present invention take a SiC VDMOSFET having N-type channels as an explanatory embodiment. Based on the same configuration manners, it is obvious that transistor structures having P-type channels may be applied as well, when P-type doped ions (for instance, aluminum (Al)) are used in the second ion implantation process IMP2. According to one preferred embodiment of the present invention, the type of ion used in the second ion implantation process IMP2 when performing such process step can be preferably selected as phosphorus (P).

As a result, by employing the second ion implantation process IMP2 in the step of S210, the amorphous layer 80 as shown in FIG. 8, can be successfully formed on a top surface of the JFET region 46. And since the second ion implantation process IMP2 uses lower ion implantation energy, it is applicable to control the formed amorphous layer 80 merely having a thickness less than 100 nm. Meanwhile, a single crystal layer having a single crystal state or a polycrystalline layer having a polycrystalline state can be maintained and kept in the JFET region underneath the amorphous layer 80.

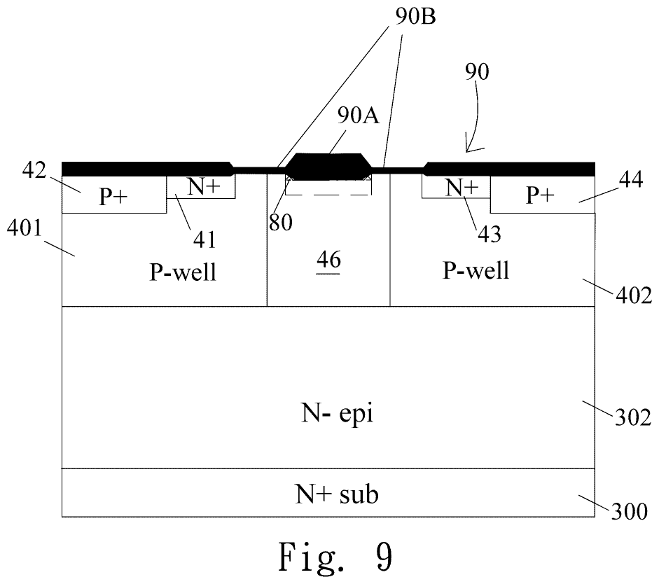

And afterwards, as illustrated in the step of S212 in FIG. 2, the present invention proceeds to remove the previously used sidewall barrier layers 70, the first hard mask layer 51 and the second hard mask layer 52, and the remaining processes are the same as those in the current VDMOSFET fabrication process. After all ion implantation processes are complete, annealing is applied, and recrystallization of the ions to a single crystal or polycrystalline state will generate at regions where high-temperature ion implantation processes are carried out. However, the amorphous layer 80 is unchanged and still having a nearly amorphous state. As such, the present invention proceeds to perform a thermal oxidation process in order to grow a gate oxide layer. In such thermal oxidation process, oxygen (O₂), water molecule (H₂O), or a mixture of hydrogen (H₂) and oxygen (O₂) can be used. It is to be understood that, when the thermal oxidation process is applied to a silicon carbide (SiC) substrate, since a thermal oxidation rate of the amorphous layer is mostly 2 to 9 times greater than the thermal oxidation rate of the single crystal layer or of the polycrystalline layer, a gate oxide structure 90 as illustrated in FIG. 9 can be effectively formed. More specifically, when the performed thermal oxidation process is a wet oxygen thermal oxidation process, then the thermal oxidation rate of the amorphous layer can be up to 4 to 9 times greater than the thermal oxidation rate of the single crystal layer or of the polycrystalline layer. On the other hand, when the performed thermal oxidation process is a dry oxygen thermal oxidation process, then the thermal oxidation rate of the amorphous layer is twice the thermal oxidation rate of the single crystal layer or of the polycrystalline layer. As a result, when oxygen (O₂) and/or water molecule (H₂O) can be alternatively used in the thermal oxidation process, the above mentioned wet oxygen thermal oxidation process and dry oxygen thermal oxidation process are included. On account of the above, it is derived that, according to the present invention, a thermal oxidation rate of the amorphous layer 80 can be generally 2 to 9 times greater than the thermal oxidation rate of the single crystal layer or of the polycrystalline layer.

And yet furthermore, as people skilled in the arts should know, the thickness of the formed gate oxide structure 90, can be controlled and determined according to various conditions of performing the foregoing thermal oxidation process, including: process temperature, oxidation time, and so on. Certain process flexibility is allowed and practical. It is worth emphasizing that, the present invention is definitely not limited to the above-mentioned thickness, dimensions or process parameters, including process temperature, process time, and reaction ions, gas, and so on, which were disclosed in the previously described embodiments. For people who are skilled in the art and with ordinary knowledge in the field, modifications without departing from the spirit of the present invention are permitted. However, within the scope of its equality, such modifications should still fall into the scope and claims of the present invention.

In details, according to the disclosed process techniques in the present invention, it is believed that after the foregoing thermal oxidation process is performed, as illustrated in FIG. 9, since the thermal oxidation rate of the amorphous layer 80 is greatly higher than that of the channel region and of the JFET region, until the amorphous layer 80 is completely oxidated and consumed, the formed gate oxide structure will eventually be able to have a significantly thicker thickness than the other gate oxide layer in the remaining region. As the Application has disclosed earlier, the implantation conditions and parameters of the second ion implantation process IMP2 also decides the thickness of the gate oxide structure to be formed. To sum above, it is believed that, by employing the disclosed fabrication process method of the present invention, the formed gate oxide structure 90 is fabricated in a terraced gate oxide structure, including at least a terraced region 90A and a channel region 90B, which is adjacent to and connecting with the terraced region 90A. In addition, according to the embodiment of the present invention, the gate oxide thickness in the terraced region 90A is more than twice, even can be 4 times greater than the gate oxide thickness in the channel region 90B.

Meanwhile, according to the embodiment of the present invention, the terraced region 90A is formed to have a gate oxide thickness configured as extending down to a bottom of the amorphous layer 80, such that a bottom of the gate oxide layer in the terraced region 90A is lower than the top surface of the JFET region 46.

Subsequently, please find Table 1 as provided in the following. The Applicants of the present invention are hereinafter providing relevant experimental data to support and verify that the disclosed technical contents of the present invention are effective. Generally speaking, after a room temperature ion implantation process is carried out to form an amorphous 4H-SiC layer, and even after a 1700° C. annealing process is applied for 30 minutes, it still cannot return to a single crystal state. And hence, when undergoing a wet oxygen thermal oxidation process, the thermal oxidation rate of the amorphous layer can be obtained as 4 to 9 times more than that of the 4H-SiC layer having single crystal state. As a result, it is apparent that when employing such process to the disclosed second ion implantation process IMP2 and the subsequent thermal oxidation process in the present invention, the grown gate oxide layer thickness from the amorphous layer 80 can be more than twice the thickness of the amorphous layer itself. As a result, a greatly reduced parasitic gate to drain capacitance (C_{GD}) is accomplished, implementing the inventive effectives of the present invention.

TABLE 1

| | | RT ion implantation |
|---|---|---|
| | | process forming an |
| wet oxygen (H₂O) | 4H—SiC (0001) | amorphous layer and |
| thermal oxidation | plane having single | annealing at |
| process | crystal state | 1700° C./30 minutes |
| 1100° C./300 minutes | growing gate oxide | growing gate oxide |
| | thickness of 66.6 nm | thickness of 281 nm |
| 1200° C./75 minutes | growing gate oxide | growing gate oxide |
| | thickness of 34.2 nm | thickness of 312 nm |

According to one preferred embodiment of the present invention, since approximately 46% of the silicon carbide material is consumed in the thermal oxidation process in step S212, the formed thick gate oxide layer merely has half of its thickness which is above the original silicon carbide surface. In addition, the gate oxide thickness is gradually increased. Based on such technical characteristics, in addition to reducing the parasitic gate to drain capacitance (C_{GD}), the terraced gate oxide structure formed by the present invention is also a semi-sunken gate oxide layer structure. It is advantageous of reducing the corner curvature of the gate electrode and the electric crowding and enhancement effect at the gate oxide layer thickness transition (from thin to thick) at the same time, whereby breakdown voltages and reliability of the power device when adopting the present invention can be significantly improved.

And further in another aspect of the present invention, since the second ion implantation process is performed to form an amorphous layer, and even after the amorphous layer is consumed and oxidated in the following thermal oxidation process, a single crystal layer having single crystal state is still maintained at a bottom of the JFET region. As known, the dopant concentration of such region will be higher than that of a conventional JFET region, and therefore, the reduced electron concentration in the accumulation layer due to a thicken gate oxide layer, under the device operating at on state can be avoided. The increasement of specific on resistance (R_{on,sp}) is suppressed. And furthermore, it may be also possible and practical to reduce the R_{on,sp}.

As a result, it is believed that the present invention has disclosed an effective fabrication method for forming a terraced gate oxide structure. In the beginning, a conventional high temperature JFET ion implantation process is applied first, and afterwards, sidewall barrier layers are provided. After the sidewall barrier layers are disposed, a second ion implantation process is then applied at room temperatures, so as to form an amorphous layer at a top surface of the JFET region. In view of the technical contents of the present invention, since the thermal oxidation rate of the amorphous layer is significantly greater than the thermal oxidation rate of its channel region and JFET region, a terraced gate oxide structure having thick gate oxide thickness is successively formed. As a result, it is believed that, not only the parasitic gate to drain capacitance (C_{GD}) can be effectively reduced, but also the corner curvature of the gate electrode can be reduced at the same time. In addition, since the bottom of the formed gate oxide structure is down below its device surface, it is believed that not only the C_{GD} is reduced, but also the conventional electric field crowding and enhancement effect is suppressed, and the device's reliability degradation is avoided. When the present invention is widely applied to any power device having the VDMOSFET structure, it is believed to be beneficial to optimizing the breakdown voltages and voltage withstand capability of the power device.

As a result, on account of the above disclosed technical contents, it is believed that the present invention certainly proposes a fabrication method for forming a terraced gate oxide and the terraced gate oxide structure formed by using the same. As indicated in the drawings in FIG. 3˜FIG. 9 of the present invention, the formed terraced gate oxide structure includes at least a terraced region 90A, having a gate oxide thickness configured as extending down to a bottom of the amorphous layer; and a channel region 90B. According to the embodiment of the present invention, the channel region 90B is adjacent to and connecting with the terraced region 90A, and the gate oxide thickness in the terraced region 90A is more than twice the gate oxide thickness in the channel region 90B. Therefore, on account of such technical features of the present invention, the proposed process method and formed terraced gate structure are beneficial to (1) decreasing the conventional parasitic gate to drain capacitance C_{GD}, (2) reducing gate electrode corner curvature, and (3) optimizing the reliability of the power device which the present invention is applied to.

Moreover, after the disclosed terraced gate oxide structure of the present invention is formed, a plurality of post end process may be subsequently carried out by people skilled in the arts and having ordinary knowledge backgrounds. The plurality of post end process may include, and not limited to: depositing a dielectric layer on the gate metal layer (dielectric deposition), defining and etching at least one metal contact window, metal deposition, metal etching, and so on. Since these post end processes are basically the same as they are performed in the current processes of the VDMOSFETs, the present invention is therefore not repeated here in after and not intended to provide detailed descriptions. Related descriptions can be referred in the technical backgrounds when necessary.

To sum up, the technical spirits of the present invention lie in forming a terraced gate oxide structure on a basis of VDMOSFET structure. Due to the terraced structure of the formed gate oxide layer, the parasitic gate to drain capacitance C_{GD} can be effectively reduced. In addition, apart from the reduced C_{GD}, the commonly generated electric field crowding and enhancement effects at the gate corners and issues related to such effect are believed to be suppressed as well.

Apart from the above, according to the process method disclosed in the present invention, its application field is certainly not limited to the N-type silicon carbide substrate but can also be widely applied to a variety of semiconductor substrates, including transistors with an N-type channel or a P-type channel. Among the technical contents, it is believed that the semiconductor substrate, the epitaxial layer, the first heavily doped region and the third heavily doped region have a first semiconductor conductivity type. On the other hand, the first well region, the second well region, the second heavily doped region and the fourth heavily doped region have a second semiconductor conductivity type. And the first semiconductor conductivity type and the second semiconductor conductivity type are opposite conductivity types. For instance, according to one embodiment of the present invention, when the first semiconductor conductivity type is an N-type semiconductor conductivity type, the second semiconductor conductivity type is a P-type semiconductor conductivity type. On the contrary, according to another embodiment of the present invention, when the first semiconductor conductivity type is a P-type semiconductor conductivity type, then the second semiconductor conductivity type will be an N-type semiconductor conductivity type. The present invention is not limited by the certain semiconductor conductivity types used in the circuit configurations. Also, the present invention is not limited by the type of channels (N-type channel or P-type channel) used in the circuit configurations. In other words, those skilled in the art are acknowledged to make adequate modifications and variations based on the technical spirits of the present invention, depending on their actual device specifications, and yet such modifications and variations should still fall within the scope of the present invention.

And further in one more applicable aspect of the present invention, when applying the disclosed fabrication process method and its terraced gate oxide structure formed thereof the present invention, it is believed that its application field is not limited to the foregoing VDMOSFETs. According to the variant embodiments of the present invention, it can alternatively be further widely applied to any power device which, for example, includes the VDMOSFET structure, an Insulated Gate Bipolar Transistor (IGBT) structure, and so on. From this point of view, it is believed that when compared with the prior arts, the present invention is characterized by having better industrial compatibility and wider application than the prior arts.

In general, for those skilled in the art with general knowledge backgrounds, on a basis of without departing from the technical spirits of the present invention, relevant embodiments are disclosed. And so, the present invention claims the various modifications and/or variations based on equality.

As a result, to sum above, as compared with the prior arts, it is asserted that through the embodiments and the process method disclosed in the present invention, the gate to drain capacitance in the disclosed transistor structure can be effectively reduced under the same applied voltage, thereby enhance the breakdown voltage of the device. The present invention is both innovative and practical. In addition, the present invention can also effectively solve the electric field enhancement and crowding effect occurring at the gate electrode corners on both sides of the gate bottom, thereby avoiding the existing deficiencies in the prior arts. Also, in addition to the silicon carbide substrates, a plurality of various substrates made of other semiconductor materials, such as silicon (Si), etc. are applicable as well. Therefore, as a matter of fact, the Applicants assert that the present invention is instinct, effective and highly competitive for the incoming technologies, industries and researches developed in the future. And since the technical features, means and effects achieved by the present invention are significantly different from the current solutions and can not be accomplished easily by those who are familiar with the industry, it is thus believed that the present invention is indeed characterized by patentability and shall be patentable soon in a near future.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A fabrication method for forming a terraced gate oxide, applicable to a high power device, the fabrication method comprising:
providing a semiconductor substrate and forming an epitaxial layer on the semiconductor substrate, wherein a first well region and a second well region are configured on the epitaxial layer, a first heavily doped region and a second heavily doped region are formed in the first well region, a third heavily doped region and a fourth heavily doped region are formed in the second well region, and a junction field effect transistor (JFET) region is formed between the first well region and the second well region;
providing a first hard mask layer and a second hard mask layer, wherein the first hard mask layer is disposed on the first heavily doped region, the second heavily doped region and the first well region, the second hard mask layer is disposed on the third heavily doped region, the fourth heavily doped region and the second well region, and a first spacing is formed between the first hard mask layer and the second hard mask layer;
performing a first ion implantation process through the first spacing;
forming a sidewall barrier layer on one sidewall of the first hard mask layer and on one sidewall of the second hard mask layer, wherein the sidewall barrier layer is disposed corresponding to the sidewall of the first hard mask layer and corresponding to the sidewall of the second hard mask layer, and the sidewall of the first hard mask layer is opposite to the sidewall of the second hard mask layer, and wherein a second spacing is formed between the first hard mask layer covered with the sidewall barrier layer and the second hard mask layer covered with the sidewall barrier layer, and the second spacing is less than the first spacing;
performing a second ion implantation process through the second spacing for amorphizing the JFET region and forming an amorphous layer on a top surface of the JFET region; and
performing a thermal oxidation process after removing the sidewall barrier layer, the first hard mask layer and the second hard mask layer, such that the amorphous layer is oxidized and the terraced gate oxide is formed in the high power device by oxidizing amorphous layer.

2. The fabrication method for forming the terraced gate oxide according to claim 1, wherein the sidewall barrier layer is made of silicon dioxide (SiO₂), silicon nitride (Si₃N₄), polysilicon (poly-Si), or other solid films made of semiconductor materials that are resistant to the second ion implantation process.

3. The fabrication method for forming the terraced gate oxide according to claim 1, wherein a thickness of the sidewall barrier layer is between 0.1 μm and 0.5 μm.

4. The fabrication method for forming the terraced gate oxide according to claim 1, wherein a process temperature of the first ion implantation process is greater than 500 Celsius degrees (° C.).

5. The fabrication method for forming the terraced gate oxide according to claim 1, wherein an ion implantation energy of the first ion implantation process is between 100 keV and 1000 keV.

6. The fabrication method for forming the terraced gate oxide according to claim 1, wherein an ion implantation dosage of the first ion implantation process is between 10¹¹ cm⁻² and 10¹³ cm⁻².

7. The fabrication method for forming the terraced gate oxide according to claim 1, wherein a process temperature of the second ion implantation process is at room temperatures.

8. The fabrication method for forming the terraced gate oxide according to claim 1, wherein an ion implantation energy of the second ion implantation process is between 5 keV and 30 keV.

9. The fabrication method for forming the terraced gate oxide according to claim 1, wherein an ion implantation dosage of the second ion implantation process is between 10¹⁴ cm⁻² and 10¹⁶ cm⁻².

10. The fabrication method for forming the terraced gate oxide according to claim 1, wherein the second ion implantation process uses ions, including phosphorus (P), nitrogen (N), argon (Ar), aluminum (Al), silicon (Si), oxygen (O), other N-type or P-type dopants, or inert ions.

11. The fabrication method for forming the terraced gate oxide according to claim 1, wherein in the step of forming the sidewall barrier layer further comprises:
using a low-pressure chemical vapor deposition (LPCVD) process to deposit a barrier layer; and
using an anisotropic etching process to etch the barrier layer so as to form the sidewall barrier layer disposed corresponding to the sidewall of the first hard mask layer and the sidewall barrier layer disposed corresponding to the sidewall of the second hard mask layer, such that the second spacing is formed there in between.

12. The fabrication method for forming the terraced gate oxide according to claim 1, wherein a thickness of the amorphous layer is less than 100 nm.

13. The fabrication method for forming the terraced gate oxide according to claim 1, wherein the JFET region underneath the amorphous layer is a single crystal layer or a polycrystalline layer.

14. The fabrication method for forming the terraced gate oxide according to claim 13, wherein a thermal oxidation rate of the amorphous layer is 2 to 9 times greater than the thermal oxidation rate of the single crystal layer or of the polycrystalline layer.

15. The fabrication method for forming the terraced gate oxide according to claim 1, wherein the terraced gate oxide includes a terraced region and a channel region, and a gate oxide thickness in the terraced region is more than twice the gate oxide thickness in the channel region.

16. The fabrication method for forming the terraced gate oxide according to claim 15, wherein the gate oxide thickness in the terraced region is configured as extending down to a bottom of the amorphous layer.

17. The fabrication method for forming the terraced gate oxide according to claim 15, wherein a bottom of a gate oxide layer in the terraced region is lower than the top surface of the JFET region.

18. The fabrication method for forming the terraced gate oxide according to claim 1, wherein oxygen (O₂), water molecule (H₂O), or a mixture of hydrogen (H₂) and oxygen (O₂) is used in the thermal oxidation process.

19. The fabrication method for forming the terraced gate oxide according to claim 1, wherein the semiconductor substrate, the epitaxial layer, the first heavily doped region and the third heavily doped region have a first semiconductor conductivity type, the first well region, the second well region, the second heavily doped region and the fourth heavily doped region have a second semiconductor conductivity type, and the first semiconductor conductivity type and the second semiconductor conductivity type are opposite conductivity types.

20. The fabrication method for forming the terraced gate oxide according to claim 1, wherein the semiconductor substrate of the high power device is made of semiconductor materials including silicon (Si) and silicon carbide (SIC).

21. The fabrication method for forming the terraced gate oxide according to claim 1, wherein the second heavily doped region is disposed adjacent to the first heavily doped region, and the second heavily doped region and the first heavily doped region are commonly disposed in the first well region.

22. The fabrication method for forming the terraced gate oxide according to claim 21, further comprising using a source ion implantation process to form the first heavily doped region in the first well region.

23. The fabrication method for forming the terraced gate oxide according to claim 1, wherein the fourth heavily doped region is disposed adjacent to the third heavily doped region, and the fourth heavily doped region and the third heavily doped region are commonly disposed in the second well region.

24. The fabrication method for forming the terraced gate oxide according to claim 23, further comprising using a source ion implantation process to form the third heavily doped region in the second well region.

25. The fabrication method for forming the terraced gate oxide according to claim 1, wherein the high power device includes a Vertical Double Diffused Metal Oxide Semiconductor Field Effect Transistor (VDMOSFET) structure, or an Insulated Gate Bipolar Transistor (IGBT) structure.

26. The fabrication method for forming the terraced gate oxide according to claim 1, wherein the first hard mask layer and the second hard mask layer are made of silicon dioxide (SiO₂).

27. A gate oxide structure formed by using the fabrication method for forming the terraced gate oxide according to claim 1, comprising:
a terraced region, having a gate oxide thickness configured as extending down to a bottom of the amorphous layer; and
a channel region, adjacent to and connecting with the terraced region, wherein the gate oxide thickness in the terraced region is more than twice the gate oxide thickness in the channel region.

28. The gate oxide structure formed by using the fabrication method for forming the terraced gate oxide according to claim 27, wherein a bottom of a gate oxide layer in the terraced region is lower than the top surface of the JFET region.

29. The gate oxide structure formed by using the fabrication method for forming the terraced gate oxide according to claim 27, wherein the JFET region underneath the amorphous layer is a single crystal layer or a polycrystalline layer.

30. The gate oxide structure formed by using the fabrication method for forming the terraced gate oxide according to claim 29, wherein a thermal oxidation rate of the amorphous layer is 2 to 9 times greater than the thermal oxidation rate of the single crystal layer or of the polycrystalline layer.

31. The gate oxide structure formed by using the fabrication method for forming the terraced gate oxide according to claim 27, wherein a thickness of the amorphous layer is less than 100 nm.
